(19) United States
(12) Patent Application Publication
(10) Pub. No.: US 2025/0169378 A1
(43) Pub. Date: May 22, 2025

(54) QUANTUM DEVICE AND ASSOCIATED METHOD FOR MANUFACTURING

(71) Applicant: COMMISSARIAT A L'ENERGIE ATOMIQUE ET AUX ENERGIES ALTERNATIVES, PARIS (FR)

(72) Inventor: Benoit BERTRAND, GRENOBLE CEDEX (FR)

(21) Appl. No.: 18/954,884

(22) Filed: Nov. 21, 2024

(30) Foreign Application Priority Data
Nov. 21, 2023 (FR) 2312796

(51) Int. Cl. H10N 60/10; B82Y 10/00; H10N 60/01

(52) U.S. Cl. CPC H10N 60/128; H10N 60/01; H10N 60/11; B82Y 10/00

(57) ABSTRACT

A quantum device includes a semiconductor layer adapted to form a two-dimensional array of quantum dots, the semiconductor layer having a front face, a dielectric, disposed on the front face of the semiconductor layer, first gates and second gates to control the quantum dots, the first gates and the second gates extending directly over the dielectric, each second gate intersecting the first gates, charge detectors, each charge detector including a conductive island, a source and a drain, the conductive island of each charge detector being formed between two adjacent first gates and directly over the dielectric.

### TECHNICAL FIELD OF THE INVENTION

The technical field of the invention is that of quantum electronics, and more particularly quantum electronic devices and the manufacture thereof.

### TECHNOLOGICAL BACKGROUND OF THE INVENTION

The use of quantum states at two measurable levels as information vectors, also referred to as “qubits” for “quantum bits”, and the laws of quantum mechanics (superposition, entanglement, measurement) offers the possibility of developing quantum algorithms that outperform some classes of conventionally used algorithms. To implement them, thousands of qubits are required. Finally, three types of operation have to be able to be performed on the qubits: initialisation in a known state, manipulation (logic gates on one or more qubits), and reading these qubits.

Semiconductor technologies capable of manipulating qubits comprise islands, also referred to as quantum dots, produced in nanometric confinement structures defined, for example, electrostatically within a semiconductor layer. Quantum dots ensure confinement of elementary charges, i.e. electrons or holes, and the quantum information is coded on the spin of these particles, for example.

For a quantum dot to be initialised with a single electron or hole, for example, it has to be coupled to read electronics capable of determining the number of charges in the quantum dot.

The use of additional devices coupled to read electronics, such as charge detectors measured in current or reflectometry, enables charge number detection to be more effective than in-situ detection methods.

Single electron transistors (SET) are among the most efficient charge detectors.

In general, a SET comprises a quantum island, two charge reservoirs, also referred to as drain and source, and a gate contact.

The quantum island is connected to each of the reservoirs by at least one junction, for example a tunnel junction or tunnel coupling.

The charge reservoirs (drain and source) are considered to be bulk metallic materials whose electrons obey the Fermi-Dirac statistics, and the island is, for example, a metal grain a few nanometres in size. The gate contact is typically separated from the island by a layer of dielectric material. The tunnel junction is, for example, formed by another layer of dielectric material, referred to as a tunnel junction, arranged so as to separate the island from the charge reservoirs.

One or more electrodes are additionally connected to the charge reservoirs and the gate contact to apply a voltage to these elements.

SETs work by capacitive coupling with the quantum dot, so a change in the number of charges in the quantum dot can affect impedance of the SET, for example.

This detection, or reading, of the resulting charge is generally carried out by current (in transport) or by reflectometry with the use of an LC resonator.

When the SET is read by current, its drain and source are biased independently of each other. In other words, two independent charge reservoirs (source and drain) are required. When the SET is read by reflectometry, its drain and source are biasable to the same potential, and only one charge reservoir (drain or source) is needed.

Integrating SETs as close as possible to the qubits would be advantageous for improving detection sensitivity. However, SETs, and in particular current-read SETs, are expensive in terms of overall size due to the large number of elements that make them up. Their integration in the qubit plane reduces the number of qubits that can be integrated per unit area, and/or requires longer-range interactions between neighbouring qubits to enable interconnectivity to at least 4 nearest neighbours.

In the absence of a mechanism enabling long-range interaction between qubits, SETs are generally integrated into the periphery of an array of quantum dots. The drawback is that the size of this array need to be reduced to a few quantum dots per side to enable the qubits disposed in the centre of the array to be read.

It is additionally suggested integrating and connecting charge detectors in planes different from the plane comprising the quantum dots. In this case this is referred to as circuits with a non-planar architecture, also known as “3D” for “3-dimensional”.

Patent application FR 3 066 297 thus provides a parallel-control quantum electronic circuit comprising a semiconductor layer receiving an array of qubits, a network of electrodes disposed on either side of this semiconductor layer, and a plane stacked on the semiconductor layer comprising an array of charge detectors. Thus, each level, or each plane, of the quantum device is dedicated to a specific function.

This solution has the advantage that each qubit is connected to at least one charge detector located in vertical alignment therewith, whatever the qubit considered in the array.

However, the architecture of this circuit is particularly complex, due in particular to the high density of vias and interconnections required to connect the different planes of the device. Hence, some manufacturing steps can be difficult to perform.

Thus, there is currently no satisfactory solution for integrating SETs into high-density 2D quantum electronic circuits. There is thus still a need for a solution of integrating transport-measured charge detectors into arrays of two-dimensional quantum dots, which allows good capacitive coupling between these charge detectors and the quantum dots while being simple to implement.

### SUMMARY OF THE INVENTION

The present invention offers a solution to the problems previously discussed by making it possible to reduce the overall size and complexity of current-read charge detectors on the chip.

More particularly, a first aspect of the invention provides a quantum device comprising:
a semiconductor layer adapted to form a two-dimensional array of quantum dots, the semiconductor layer having a front face,
a dielectric, disposed on the front face of the semiconductor layer,
first gates and second gates to control the quantum dots, the first gates and second gates extending directly over the dielectric, each second gate intersecting the first gates, the first and second gates defining a network of two-dimensional meshes, each two-dimensional mesh facing a quantum dot,
charge detectors, each charge detector comprising a conductive island, a source and a drain, the conductive island of each charge detector being formed at the level of a two-dimensional mesh, between two adjacent first gates and directly over the dielectric.

Thus, advantageously according to the invention, the conductive island of each charge detector is formed at the same level as that of the first and second gates (the term “same level” here means between the lower face and the upper face of the first gates). This results in a compact quantum device (in terms of height). It also makes it possible to obtain a quantum device that only uses a single semiconductor substrate and whose manufacture does not involve bonding steps.

In addition, by virtue of the conductive island that is laid on the dielectric in a two-dimensional mesh, there is good capacitive coupling between the quantum dot formed in vertical alignment with the two-dimensional mesh and neighbouring quantum dots. This proximity improves detection sensitivity of the quantum device.

It is appropriate to add that forming the conductive islands between first gates offers the advantage of being able to use these first gates as an alignment reference at the time of manufacturing the conductive islands. In other words, the first gates enable the conductive islands to “self-align”. This self-alignment facilitates these manufacturing steps.

The quantum device according to the invention thus offers an integration solution compatible with industrial manufacturing methods and large-scale quantum dot integration, as well as providing the required proximity between the current-read charge detectors and the quantum dots.

Further to the characteristics just discussed in the preceding paragraph, the quantum device according to the first aspect of the invention may have one or more complementary characteristics from among the following, considered individually or according to any technically possible combinations:
the conductive island of each charge detector being integrated into one of the second lines of gates
the drain of each charge detector comprises a conductive via coated with an electrically insulating material, the coated conductive via having an end disposed in contact with a barrier layer disposed in vertical alignment with the conductive island of said charge detector.
the conductive island of each charge detector is formed in a gate for controlling the quantum dots distinct from the first gates, said gate intersecting the first gates and extending directly over the dielectric, said gate having insulating recesses covered with an electrically insulating layer, the insulating recesses being disposed at the intersections of said gate with the first gates, each insulating recess accommodating a first gate, the insulating recesses defining in said gate a plurality of lower conductive regions extending directly over the dielectric, and a continuous upper conductive region.
said gate is one of the second gates.
Alternatively, said gate is a third gate in a set of third gates for controlling chemical potential of the quantum dots, each third gate being disposed in vertical alignment with the quantum dots formed along a column or diagonal of the array of quantum dots.
Said gate has an inner structure of a first type comprising:
   a tunnel layer covering each insulating recess in said gate,
   every fourth lower conductive regions extending the upper conductive region towards the dielectric, said every fourth lower conductive regions defining three complementary lower conductive regions,
   the two lower conductive regions at the ends of the three complementary lower regions being covered with an upper barrier layer, the upper barrier layer being disposed on the tunnel layers,
   the lower conductive region in the centre of the three complementary lower conductive regions extends to a conductive via coated with an electrically insulating material, said conductive via passing through the upper region to the upper barrier layer.
a second gate out of two, or a third gate out of two, can then have the inner structure of the first type.
the conductive islands are then disposed staggered relative to one another.
Alternatively, each second gate, or each third gate, can have the inner structure of the first type.
As an alternative to the structure of the first type, said gate has an inner structure of a second type comprising:
   A barrier layer covering all the lower conductive regions of said gate, the barrier layer being continuous and disposed on the insulating recesses of said gate,
   Conductive vias coated with electrically insulating material passing through the upper conductive region to the barrier layer, each conductive via having an end disposed for one part in vertical alignment with a lower conductive region and for the other part in vertical alignment with an insulating recess adjacent to said lower conductive region,
a second gate out of two, or a third gate out of two, can then have the inner structure of the second type.
Alternatively, each second gate, or each third gate, can have the inner structure of the second type.
The quantum device can comprise addressing gates to address the drains of the charge detectors, each addressing gate being coupled to conductive vias located on a same column of the array of quantum dots.
When said gate has the inner structure of the first or second type, the upper region of said gate is coupled to a voltage source to address the sources of charge detectors formed in said gate.
the quantum device may comprise gates for controlling chemical potentials of the conductive islands, each control gate extending over one of the first gates and being housed under the insulating recesses of the second gates at the intersections of the first and second gates.
the semiconductor layer comprises holes to form quantum dots,
The holes are disposed in vertical alignment with the intersections between the first and second gates.

A second aspect of the invention relates to a method for manufacturing a quantum device comprising charge detectors, each charge detector comprising a conductive island, a drain and a source, the method comprising the following steps of:
providing a semiconductor layer adapted to form a two-dimensional array of quantum dots, said semiconductor layer having a front face, said semiconductor layer comprising a dielectric disposed on the front face and first gates to control the quantum dots, the first gates extending directly over the dielectric,
coating the flanks and upper face of each first gate to house each first gate under an insulating recess,
defining conductive islands from the first coated gates, each conductive island extending between two adjacent first gates and directly over the dielectric,
forming, from the conductive islands defined, second gates to control, with the first gates, the quantum dots, each second gate extending directly over the dielectric and intersecting the first gates, the first and second gates forming a network of two-dimensional meshes on the dielectric.

Preferably, the conductive island definition step may comprise the following sub-steps of:
filling, with a conductive material, the spaces of the dielectric which are delimited by two adjacent first gates coated, filling stopping at the insulating recesses,
forming a barrier layer over the entire surface after filling,
structuring the barrier layer to form barrier strips oriented at a predetermined angle relative to the first gates.

Preferably, the predetermined angle is such that the barrier strips are oriented at 45° relative to the direction of the first gates, the barrier strips extending, in the direction perpendicular to the first gates, over four adjacent conductive strips.

Preferably, the manufacturing method can comprise, after the step of forming the second gates, a step of making conductive vias coated with an electrically insulating material, each conductive via passing through an upper region of one of the second gates with stopping on a region of a dielectric barrier strip, the conductive via forming the drain of the conductive island defined in vertical alignment with the region of the barrier strip.

The invention and its different applications will be better understood upon reading the following description and upon examining the accompanying figures.

### BRIEF DESCRIPTION OF THE FIGURES

The figures are set forth by way of indicating and in no way limiting purposes of the invention.

FIG. 1 shows a schematic representation in a top view of a quantum device according to one embodiment of the invention,

FIG. 2 shows a schematic representation in a cross-section view of the quantum device represented in FIG. 1,

FIG. 3A shows a first schematic perspective representation of part of the quantum device represented in FIG. 1,

FIG. 3B shows a second schematic perspective representation of part of the quantum device represented in FIG. 1,

FIG. 3C shows a third schematic perspective representation of part of the quantum device represented in FIG. 1,

FIG. 4 shows a schematic representation in a cross-section view of an alternative quantum device to the quantum device represented in FIG. 1, for forming as many charge detectors as quantum dots,

FIG. 5 schematically represents a top view of an alternative quantum device to the quantum device represented in FIG. 1, for positioning the charge detectors in vertical alignment with the quantum dots,

FIG. 6 schematically represents a top view of an alternative quantum device to the quantum device represented in FIG. 5,

FIG. 7 is a block diagram illustrating the sequence of steps of a method for manufacturing the quantum device represented in FIG. 1,

FIG. 8 is a block diagram illustrating a preferred mode of implementation of the manufacturing method represented in FIG. 8,

FIG. 9 is a block diagram illustrating a preferred mode of implementation of the manufacturing method represented in FIG. 8,

FIG. 10 is a block diagram illustrating a preferred mode of implementation of the manufacturing method represented in FIG. 8,

FIGS. 11A to 11L illustrate the steps or sub-steps of the manufacturing method represented in FIG. 7, each figure showing a perspective view and a cross-section view of one of the steps or sub-steps.

Unless otherwise specified, a same element appearing in different figures has a single reference.

### DETAILED DESCRIPTION

The present invention is within the context of quantum electronic devices as well a method for manufacturing the same. More particularly, the invention aims to enable, via transport-read charge detectors, efficient detection of the state of charge of quantum dots formed on the quantum devices. Still in particular, the invention aims to reduce space occupied by these charge detectors on the quantum device in order to provide an architecture for making large-scale spin qubits.

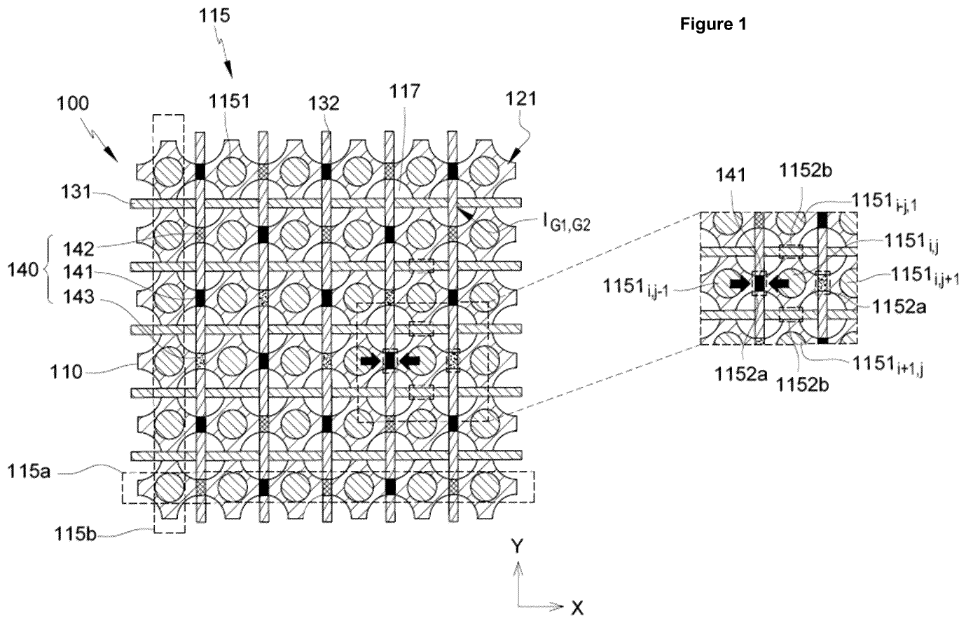

FIGS. 1, 2, 3 and 4 schematically represent a quantum device 100 (hereinafter also referred to as “device 100”) according to one embodiment.

FIG. 1 schematically shows a top view of part of the quantum device 100 according to this first embodiment.

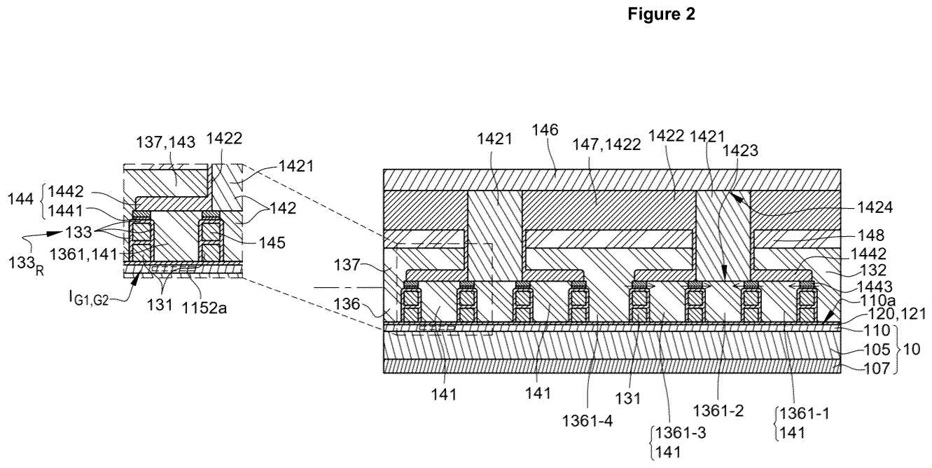

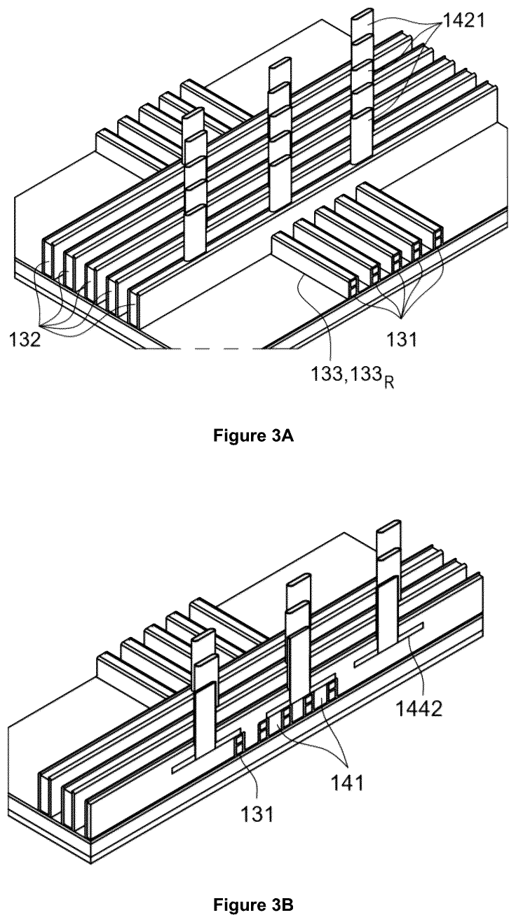

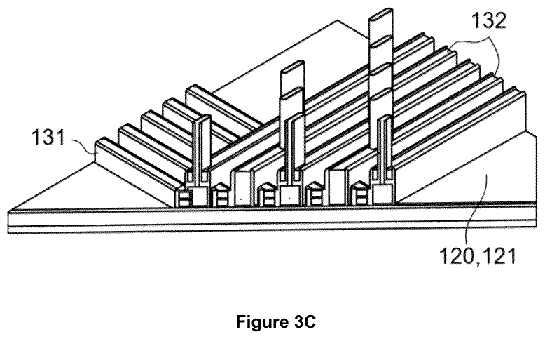

FIG. 2 and FIGS. 3A to 3C respectively show a transverse cross-section view and a perspective view of a first alternative embodiment of the quantum device 100 represented in FIG. 1.

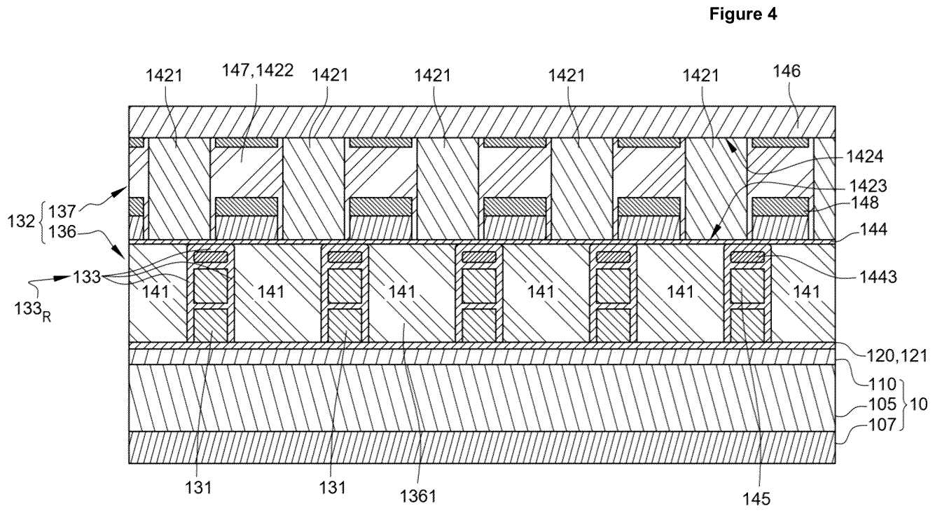

FIG. 4 shows a transverse cross-section view, in a same sectional plane as that of FIG. 2, of a second alternative embodiment of the quantum device 100 of FIG. 1.

With reference to FIG. 1, and in common with the two alternative embodiments illustrated in FIGS. 2, 3 and 4, the quantum device 100 extends in a {X,Y}plane and is formed from a semiconductor layer 110. The device 100 further comprises a dielectric 121, first and second gates 131, 132 and charge detectors 140. The first gates and the second gates are typically coupling gates. These elements are described in detail hereinafter.

In the remainder of the description, the terms “thickness” or “height” designate dimensions measured perpendicularly to the {X; Y}plane. The term “lateral dimension” designates a dimension measured in the {X; Y}plane.

It is noted that the wording “gate” can be used to herein designate a line of gates. By “line of gates” is understood a line comprising a plurality of gates.

The semiconductor layer 110 has a front face 110a, illustrated in FIG. 2.

The semiconductor layer 110 is adapted to form an array 115 of quantum dots 1151. In other words, the semiconductor layer 110 has characteristics for forming an array 115 of quantum dots 1151 therewithin. These quantum dots are represented by hatched circles in FIG. 1.

The term “array” here designates an arrangement of quantum dots in rows 115a and columns 115b (see FIG. 1).

With reference to FIG. 2 or FIGS. 3A to 3C, the semiconductor layer 110 has a thickness of between 5 nm and 35 nm and preferably between 10 nm and 20 nm, for example 15 nm.

The semiconductor layer 110 is preferably a silicon layer 110.

Preferably, this silicon layer 110 comes from a Silicon On Insulator (SOI) substrate 10.

Such a substrate 10 is illustrated in FIG. 2. It comprises a stack, from bottom to top, of a bulk semiconductor layer 107, an insulating layer 105, and the silicon semiconductor layer 110. The insulating layer 105 is disposed between the bulk semiconductor layer 107 and the semiconductor layer 110. Biasing such a substrate 10 allows electrostatic control of charge confinement in the semiconductor layer 110 and therefore offers an additional level of potential control for the device 100.

Alternatively, the semiconductor layer 110 can be a bulk silicon layer.

The semiconductor layer 110 can, alternatively, be a semiconductor heterostructure comprising a quantum well or a two-dimensional electron gas (2DEG). Such structures have interfaces with low defect densities, facilitating charge confinement and electrostatic control.

The semiconductor layer 110 can advantageously have holes 117. These holes 117 are illustrated by white circles in FIG. 1. These holes 117 can be obtained, for example, by etching the semiconductor layer 110.

The holes 117 are preferably arranged in rows and columns to form an array of holes 117. In FIG. 1, the rows of holes 117 are oriented in a first direction X corresponding to the direction of the rows 115a of quantum dots 1151. Similarly, the columns of holes 117 are oriented in a second direction Y corresponding to the direction of the columns 115b of quantum dots 1151.

The holes 117 are disposed between the rows and columns of quantum dots. Preferably, as illustrated in FIG. 1, four holes 117 flank each zone corresponding to a quantum dot 1151.

The diameter of the holes 117 is preferably between 20 nm and 50 nm. Thus, the holes 117 structure the semiconductor layer 110 to confine charges in each non-etched zone, i.e. in the zone corresponding to the quantum dot 1151. The presence of holes 117 thus facilitates formation of quantum dots 1151.

The dielectric 121 is disposed on the front face 110a of the semiconductor layer 110 and is formed of one or more layers, each layer being formed of a dielectric material (see FIG. 2, FIGS. 3A to 3C, or FIG. 4).

Preferably, as shown in FIG. 2, the dielectric 121 consists of a single layer 120 of dielectric which covers the front face 110a of the semiconductor layer 110. The dielectric layer 120 is preferably between 5 nm and 10 nm thick and is electrically insulating. The dielectric layer 120 is for example of silicon oxide (SiO₂).

According to one alternative, not represented by the figures, the dielectric layer 120 can be partially covered, i.e. covered between the first gates 131, with another dielectric layer, referred to as the “second dielectric layer”. According to this alternative, the dielectric 121 then consists of the dielectric layer 120 and the second dielectric layer covering this dielectric layer 120. The second dielectric layer can then be formed of SiO₂ or an aluminium oxide (Al₂O₃). The maximum thickness of the second dielectric layer depends on the material selected: when the material is SiO₂, the thickness is, for example, 5 nm; when the material is Al₂O₃, the maximum thickness of the spacer layer can be between 10 nm and 15 nm.

The first gates 131 and the second gates 132 are conductive strips formed from a conductive material selected from the following materials: doped crystalline silicon (or doped Poly-Si), tungsten (W), titanium nitride (TiN).

The first gates 131 extend entirely over the dielectric layer 120 of the dielectric 121, along a first direction X, illustrated in FIG. 1, which corresponds to the orientation of the rows 115a of quantum dots 1151.

Each first gate 131 has a cross-section whose height is preferably between 5 nm and 50 nm, and preferably equal to 25 nm. The lateral dimension and the height of the cross-section are preferably substantially identical. The cross-section of each first gate 131 is then a square cross-section.

Each first gate 131 is further covered, or coated, on its flanks (i.e. its lateral faces) and its upper face (i.e. the face opposite to the dielectric layer 120) with a spacer layer 133 (see FIG. 2). This spacer layer 133 is made of a dielectric material, for example SiO₂ or Al₂O₃. Its maximum thickness depends on the material selected: when the material is SiO₂, the thickness is, for example, 5 nm; when the material is Al₂O₃, the maximum thickness of the spacer layer can be between 10 nm and 15 nm.

When the dielectric 121 is formed of the dielectric layer 120 and the second dielectric layer, this second dielectric layer and the spacer layer 133 come from one and the same continuous layer 133. Thus, in this case, the spacer layer 133 continuously extends around the perimeter of the first gates and over the dielectric layer 120. This alternative embodiment is easier to perform than the alternative in which the dielectric 121 consists of the dielectric layer 120 only. Indeed, it is not necessary to structure the spacer layer 133 once it has been deposited onto the first gates 131 and the dielectric layer 120. This alternative therefore makes it possible to dispense with a step of anisotropically etching the spacer layer 133 after it has been deposited (since this etching is not necessary). On the other hand, as will be better understood later, the second gates 132 are a little further away from the semiconductor layer 110 and therefore from the quantum dots 1151. Electrostatic control of the quantum dots as well as coupling of the charge detectors 140 to the quantum dots 1151 may thus be substantially less effective.

The second gates 132 are oriented along a second direction Y different from the first direction X. This direction Y corresponds to the direction of the columns 115b of quantum dots 1151 (see FIG. 1).

In FIG. 1, the second direction is oriented at 90° relative to the first direction X. Of course, this second direction Y can be oriented at an angle different from 90° relative to the first direction X.

Each second gate 132 extends directly over the dielectric 121, which is therefore a gate dielectric, and intersects the first gates 131 at intersection zones (noted I_{G1,G2} in FIG. 1) according to a “nested” configuration.

This “nested” configuration is described in detail hereinafter, in connection with FIG. 2.

According to this nested configuration, each second gate 132 has a height which is greater than the height of the first gates 131. Preferably, the height of the second gates 132 is between 20 nm and 50 nm greater than that of the first gates 131. The lateral dimension of the second gates is preferably identical to that of the first gates.

In addition, each second gate 132 extends:
directly over the dielectric 121 (in FIG. 2, this dielectric 121 is the dielectric layer 120) between two adjacent first gates (or, in other words, in the inter-first gate spaces), and
on the spacer layer 133 covering the flanks and upper face of the first gates at the intersection zones I_{G1,G2} (see FIGS. 1 and 2).

In other words, each second gate 132 passes over, or overlaps, the first gates 131 coated with the spacer layer 133 at the intersection zones I_{G1,G2}. This overlap means that the first gates 131 are not physically intersected at the intersection zones I_{G1,G2}.

By virtue of the spacer layer 133, which is interposed between the first gates 131 and the second gates 132, each second gate 132 intersects the first gates 131 without making electrical contact with them.

In addition, as the height of the second gates 132 is greater than that of the first gates 131, first gates 131 which are housed under insulating recesses in the second gates 132 are obtained at the intersection zones I_{G1,G2}.

These insulating recesses are visible in FIG. 2 since the transverse cross-section illustrated in this figure is along a sectional plane passing through a second gate 132 at an intersection zone I_{G1,G2}. These recesses are marked with reference 133_{R} in FIG. 2. Each recess 133_{R} forms an insulating bridge under which a first gate 131 passes.

As shown in FIG. 2, the recesses 133_{R} define, in each second gate 132, a lower stage 136 and an upper stage 137 that are conductive.

The lower stage 136 has a pattern comprising a plurality of lower conductive zones 1361 (these lower conductive zones are also noted 1361-1, 1361-2, 1362-3, 1361-4 in FIG. 2).

Each lower conductive region 1361 is separated from adjacent lower conductive zones by one of the insulating recesses 133_{R}.

The upper stage 137 forms a continuous upper conductive region 137. The nested configuration therefore maintains electrical continuity along each first gate 131 and along each second gate 132.

As will be described later in the description, these lower conductive zones 136 and the upper conductive region 137 are advantageously used to form the charge detectors 140.

As shown in FIG. 1, the arrangement of the first and second gates 131, 132 also makes it possible to define on the surface of the dielectric (here the dielectric layer 120) a network of regular spaces (hereinafter also referred to as “two-dimensional meshes”). Each two-dimensional mesh corresponds to the zone of a quantum dot 1151.

Each two-dimensional mesh comprises the free dielectric space defined at the intersection between two adjacent first gates and two adjacent second gates and the closed contour formed by the portions of the gates at the intersection.

In the example of FIG. 1, the directions X, Y of the first and second gates 131, 132 are orthogonal to each other. The two-dimensional meshes are square-shaped.

The directions X, Y of the first and second gates 131, 132 can alternatively be oriented at an angle different from 90°.

When the semiconductor layer 110 includes holes 117 as illustrated in FIG. 1, directions X and Y of the first and second gates also correspond, respectively, to the directions of the rows and columns of holes 117. The first and second gates are also disposed so that there is a hole 117 facing each intersection zone I_{G1,G2}. Thus, a hole 117 is disposed at each apex of the two-dimensional meshes.

Independent control of each first and second gate 131, 132 makes it possible to control electrostatically and with short-range interactions a quantum dot 1151 in each region of the semiconductor layer 110 located in vertical alignment with a two-dimensional mesh.

This control is facilitated by the presence of the holes 117, which enable charges to be confined (non-electrostatically) at the regions of the semiconductor layer forming the quantum dots 1151.

Each region of the semiconductor layer 110 forming a quantum dot has lateral dimensions, defined in the {X,Y}plane, which are preferably between 5 nm and 100 nm, and preferably equal to 50 nm. The thickness of the region of the semiconductor layer 110 forming a quantum dot is moreover preferably between 5 nm and 30 nm, and preferably equal to 15 nm.

The distance between two neighbouring quantum dots, i.e. two quantum dots formed facing two neighbouring two-dimensional meshes, is preferably between 25 nm and 125 nm.

More precisely, control of the first and second gates enables conduction of tunnel barriers 1152a, 1152b located on either side (along directions X and Y) of each two-dimensional mesh to be controlled by field effect.

On the part of FIG. 1 representing an enlarged view of a two-dimensional mesh, these tunnel barriers 1152a, 1152b are represented by dotted rectangles. Each tunnel barrier 1152a is located facing a second gate 132 and connects the quantum dot 1151_{i,j} to the adjacent quantum dot 1151_{i,j-1} (or 1151_{i,j+1}) formed on the same row of the network of two-dimensional meshes. Each tunnel barrier noted 1152b is located facing a first gate 131 and connects the quantum dot 1151_{i,j} to the adjacent quantum dot 1151_{i-1,j} (1151_{i+1,j}) or formed on the same column of the network of two-dimensional meshes.

The tunnel barriers 1152a, 1152b preferably have lateral dimensions smaller than those of the quantum dots 1151, for example lateral dimensions of between 5 nm and 30 nm. However, their thickness is similar to that of the quantum dots 1151.

According to the above, the first gates 131 are disposed in vertical alignment with first tunnel barriers 1152b, and the second gates are disposed in vertical alignment with second tunnel barriers 1152a. Each first tunnel barrier 1152b connects two neighbouring quantum dots disposed in a same column 115b of the array of quantum dots, while each second tunnel barrier 1152a connects two neighbouring quantum dots disposed in a same row of this array 115.

Each charge detector 140 includes a conductive quantum island 141 (hereinafter also referred to as island 141) and two electrically independent charge reservoirs: a drain 142 and a source 143. It should be noted that, in the remainder of the description, drain 142 and source 143 are interchangeable.

As the drain and source are independent, each charge detector 140 can be measured by transport. Such a measurement is, for example, described in document “Observation of spin-space quantum transport induced by an atomic quantum point contact” by Koki Ono et al, Nature Communications 12, 2021.

As shown in FIGS. 2 and 3A to 3C, the island 141 of each charge detector 140 is formed between two adjacent first gates 131 and directly over the dielectric 121,120.

Thus, this island 141 is formed at the same level as that of the first and second gates 131, 132. This makes it possible to obtain a compact (in terms of height) quantum device 100. The term “at the same level” means that each island 141 is formed between the lower face of the first gates and the upper face of the second gates.

In addition, as will be described later in the description in connection with the manufacturing method, the fact of forming the conductive islands 141 between first gates 131 offers the advantage of being able to use these first gates 131 as an alignment marker at the time of the steps of manufacturing the conductive islands 141. In other words, the first gates enable the islands 141 to “self-align”. This self-alignment facilitates these manufacturing steps.

Compactness and simplicity of manufacture are key advantages for scaling up quantum processors.

In common with the two alternative embodiments illustrated in FIG. 2 and FIG. 4 respectively, each island 141 is formed in one of the lower conductive zones 1361 of a second gate 132. As previously described, these lower conductive zones 1361 are located between two first gates 131.

The island 141 of each charge detector 140 is thus “laid” on the dielectric in vertical alignment with a tunnel barrier 1152a and is coupled to both quantum dots 1151 disposed, in the plane of the semiconductor layer 110, on either side of this tunnel barrier 1152a. This coupling is depicted by arrows on the part of FIG. 1 representing an enlarged view of a two-dimensional mesh. Each charge detector 140 is then shared between at least two quantum dots 1151.

Several islands 141 are formed in a same second gate 132 (see FIG. 2).

In this second gate 132, the lower conductive zones 1361 defining an island 141 are covered with a barrier layer 144 (see FIG. 2, in particular the left-hand insert of this FIG. 2). This barrier layer 144 is arranged within the second gate 132. This barrier layer 144 has the effect of electrically isolating the island 141 from the upper conductor stage 137 and from the other islands 141 of the second gate 132. It also has the effect of allowing formation of a tunnel current therewithin.

All the charge detectors 140 in this second gate have a common source 143, formed by the upper stage 137 of this second gate. The common source 143 is connected by tunnel coupling to each conductive island 141 by virtue of the barrier layer 144.

Finally, each charge detector 140 of this second gate 132 has a drain 142, formed by a conductive via 1421 coated on its flanks with an insulating layer 1422. This insulating layer 1422 is formed of an insulating material. For example, it is formed from silicon dioxide SiO₂. The insulating layer 1422 of each drain 142 is sufficiently wide to isolate the source 143 from the drain 142. For example, when the insulating layer 1422 is formed from SiO₂, its width is 5 nm.

The conductive via 1421 coated has a lower end 1423 and an opposite upper end 1424. The conductive via 1421 coated passes through the upper stage 137 to the barrier layer 144. At least part of the barrier layer 144 is in contact with the lower end 1424 of the conductive via 1421.

By thus using regions 1361, 137 of the second gate 132 to form the conductive island 141 and one of the charge reservoirs 143, on the one hand, and to incorporate the other charge reservoir 142, on the other hand, the overall footprint (both lateral and vertical) of the charge detector 140 is reduced in the quantum device 100. This thus makes it possible to obtain a compact device 100, which is advantageous for scaling quantum processors.

The use, in particular, of the upper conductive zone 137 to form/incorporate the charge reservoirs 142, 143 offers an additional advantage for integrating the addressing functions of the charge detectors 140. Indeed, this upper conductive zone 137 is easily accessible for making electrical recontact from above and/or for making electrical recontact at the ends of the second gates 132.

Control of the source 143 can thus be made without a vertical connection (via type) by one end of a second gate 132 coupled to a voltage source.

Measurement of the island 141 can be made via the upper end 1424 of the conductive via 1421. As shown in FIGS. 2 and 4, a metallisation row 146 for polarizing the drains of a single second gate 132 may extend over the upper ends 1424 of the conductive vias 1421 formed on this second gate 132. In this case, an encapsulation layer 147 is interposed between the metallisation row 146 and the upper conductive region 137. This encapsulation layer 147 may be formed of the same material as the layer 1422 covering the conductive vias 1421. It is noted in FIGS. 2 and 3 the presence of a hard mask layer 148 interposed between the encapsulation layer 147 and the upper conductive region 137. This hard mask layer 148 is related to the manufacturing process.

In other words, the charge detectors 140 are arranged such that they form lines of charge detectors 140 and such that one among the source 143 and the drain 142 of each charge detector 140 of a same line of charge detectors 140 is in electrical contact with a same metallisation row 146, and such that the other among the source 143 and the drain 142 of each charge detector 140 is common for each charge detector 140 of a same line of charge detectors 140.

It is also possible that the conductive island 141 of each charge detector 140 is integrated into one of the second lines of gates 132.

As shown in FIGS. 2 and 4, the quantum device 100 can also advantageously comprise gates 145 for controlling chemical potential of the islands 141. These gates 145 are referred to hereafter as “gates 145 for controlling the charge detectors”.

Each gate 145 for controlling the charge detectors 140 is housed under an insulating recess 133_{R}, where it extends over a first gate 131 covered with the spacer 133.

Each island 141 is then connected to the gate 145 for controlling the charge detectors via the recesses 133_{R}.

By thus interposing the gates 145 for controlling the charge detectors 140 under the recesses 133_{R} of the second gates 132, the number of electrical interconnections required to control the charge detectors 140 is reduced. This space saving leads to a more compact quantum device 100 than solutions of prior art using superimposed semiconductor planes.

The number of conductive islands 141 formed in the same second gate 132 depends on the inner structure of this second gate 132.

According to the first alternative embodiment, illustrated in FIG. 2 and FIG. 3C, the inner structure of the second gate 132 is of a first type for forming an island 141 in every other lower conductive region 1361.

This first type also makes it possible to connect two adjacent conductive islands 141 to a same drain 142. Thus, there are fewer drains 142 (up to half as many) than charge detectors 140. This reduces the number of elements to be integrated into the quantum device 100 to form the charge detectors 140. This reduction in the number of elements helps to reduce footprint of the charge detectors in the quantum device 100.

According to this first type, the barrier layer 144 comprises a lower barrier layer 1441, also referred to as the tunnel layer 1441, and an upper barrier layer 1442.

The tunnel layer 1441 covers all the recesses 133_{R} on the upper face of the first gates 131.

For reasons relating to the manufacture of quantum device 100, tunnel layer 1441 is interposed here between insulating layer 133 (of recess 133_{R}) and a hard mask layer 1443 (see FIG. 2).

Tunnel layer 1441 has characteristics that enable tunnel coupling to be made therewithin.

In FIG. 2, the arrows depict direction of the current flowing in each island 141 of a single electron transistor SET.

The lateral dimension of the tunnel layer 1441 corresponds to the lateral dimension of the first gate 131. In the example of a first gate with a lateral dimension of 20 nm, the tunnel layer 1441 is sufficiently narrow to allow a tunnel current to flow therethrough.

The tunnel layer 1441 can be formed of aluminium oxide (Al₂O₃). Alternatively, the tunnel layer 1141 can be a layer of undoped silicon.

Preferably, tunnel layer 1441 is formed from hafnium oxide (HfO₂). This material indeed has a programmable resistance that can be adjusted to a value of between a few kiloohms and a few tens of kiloohms. The tunnel layer 1441 is preferably between 5 nm and 10 nm thick.

The upper barrier layer 1442 is disposed on the tunnel layers 1441 so that:
every fourth lower conductive region 1361-4 extends the upper conductive region 137 towards the dielectric 121,120 (In FIG. 2, the three complementary regions are noted with the references 1361-1, 1361-2 and 1361-3), and
the lower conductive region 1361-2 located in the centre of the three complementary lower conductive regions extends to the traversing via 1421, 1422 forming the drain 142.

In the remainder of the description, the lower conductive region 1361-2 located in the centre of the three complementary lower conductive regions is referred to as the “central lower region 1361-2”, while the two regions located on either side of this central region are referred to as the “lateral lower regions 1361-1, 1361-3”.

The upper barrier layer 1442 thus covers the two lower side regions 1361-1, 1361-3.

On the two recesses 133_{R} surrounding the central lower region 1361-2, the barrier layer 1442 is in contact with the insulating layer 1422 coating the traversing via 1441.

The lower side regions 1361-1 and 1361-3, covered with the upper barrier layer 1442, each form a conductive island 141.

The traversing via 1421 and the central lower region 1361-2 form a continuous conductive region. This forms the drain 142 of the two islands 141 formed in the lower side regions 1361-1 and 1361-3. Tunnel coupling between this drain 142 and the two islands 141 is performed in each of the tunnel layers 1441 disposed on either side of the central conductive region 1361-2.

The upper stage 137 (and the lower conductive region 1361-4 which extends to this upper stage 137) form the source 143 of the two islands 141 formed in the lower side regions 1361-1 and 1361-3. Tunnel coupling between the source 143 and the two islands 141 is performed in each of the tunnel layers 1441 disposed on the recesses 133 delimiting the three complementary regions.

In FIG. 2, the drain-island and source-island tunnel couplings are depicted by arrows.

As shown in FIGS. 3A to 3C, each second gate 132 may have this first type structure. Alternatively, a second gate 132 may have this first type structure.

The lower conductive regions 1361-1, 1361-3 selected to define the islands 141 in a given second gate 132 are preferentially offset relative to those selected for a neighbouring second gate 132.

In this way, and with reference to FIG. 1, the islands 141 are arranged staggered relative to each other in the assembly formed by the second gates 132. Consequently, the charge detectors 140 are also disposed staggered relative to each other. This staggered arrangement ensures good measurement sensitivity with a reduced number of charge detectors 140.

According to the second alternative embodiment, illustrated in FIG. 4, the inner structure of the second gate 132 is of a second type making it possible to form an island 141 in each lower conductive region 1361. This second type thus makes it possible, compared to the first type, to double the number of charge detectors 140 formed in a same second gate 132. There are then as many charge detectors 140 as there are quantum dots 1151.

By thus increasing the number of charge detectors 140, it is possible to measure each quantum dot 1151 as close to it as possible. This improves sensitivity of the measurement of the quantum dots.

This second type also allows a drain 142 to be connected to each island 141.

According to this second type, all the lower regions 1361 of the second gate 132 are covered with a barrier layer 144 formed by the tunnel layer 1441 previously described.

Thus, unlike the structure of the first type, the tunnel layer 1441 extends both over the recesses 133_{R} (facing the upper face of the first gates 131) and above the lower conductive regions 1361. The tunnel layer 1441 is therefore continuous.

Conductive vias 1421 coated with an insulating layer 1422 pass through the upper region 137 to the barrier layer 144.

The lower end 1423 of each conductive via 1421 is disposed on the barrier layer 144, partly in vertical alignment with a lower conductive region 1361 and partly in vertical alignment with a recess 133_{R} adjacent to the lower conductive region 1361. The insulating layer 1422 which coats the conductive via 1421 is in contact with the barrier layer 144.

Each conductive via 1421 forms the drain 142 of an island 141.

In addition, as with the structure of the first type, the upper conductive zone 137 forms the source 143 of all the islands 141 formed in this second gate 132.

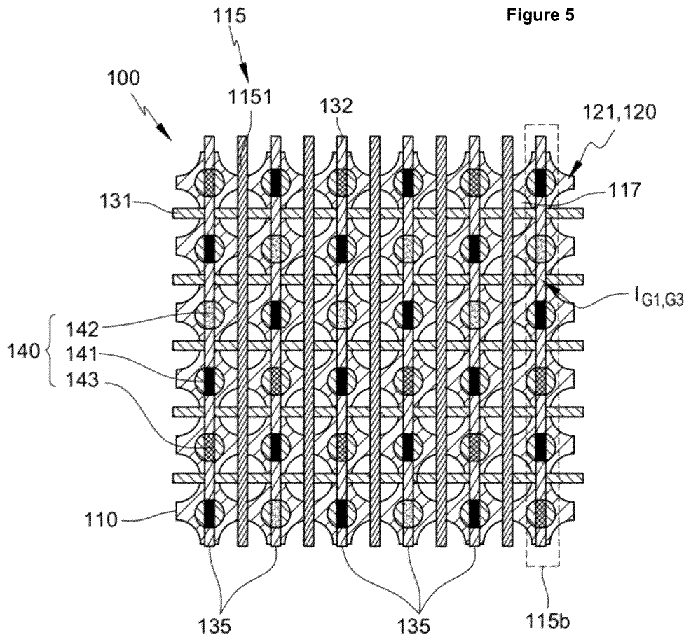

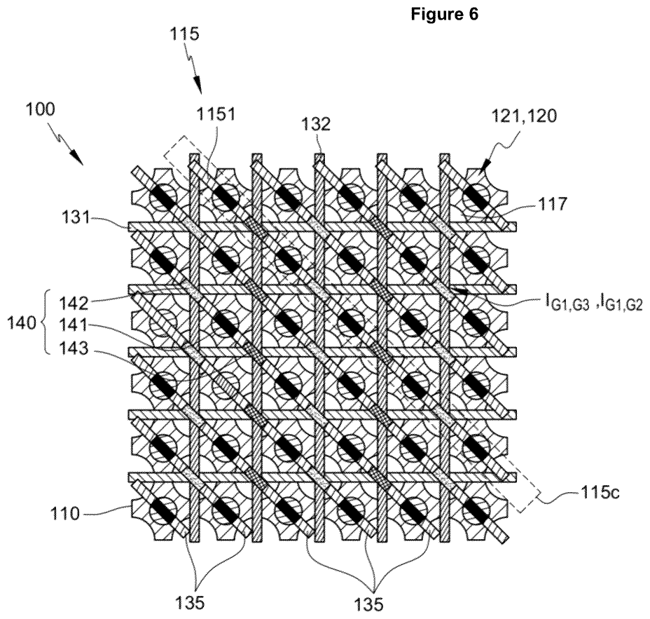

FIGS. 5 and 6 show a second embodiment of the quantum device 100.

The second embodiment differs from the first embodiment, illustrated in FIGS. 1 to 4, in that the charge detectors 140 are not formed in the second gates 132 but in third gates 135 for controlling chemical potential of the quantum dots 1151 (i.e., the third gates control the potential of the charge detectors) and thus disposed in vertical alignment with the quantum dots 1151.

This arrangement allows more localised measurement of the state of charge of the quantum dot 1151 than when the charge detector 140 is in vertical alignment with a tunnel barrier. Indeed, a charge detector 140 disposed in vertical alignment with a quantum dot is more sensitive to the same because it is closer than a charge detector disposed in vertical alignment with a tunnel barrier. It is, however, less sensitive to neighbouring quantum dots.

The second gates 132 are then covered, on their flanks and upper face, with a layer of insulating material forming a spacer similar to spacer 133. The spacer 133 makes it possible to electrically insulate the second gates 132 from the third gates 135.

The third gates 135 are conductive strips formed from a conductive material similar to that forming the first and second gates 131, 132.

As shown in FIGS. 5 and 6, these third gates 135 are distinct from the second gates 132 and are all oriented in a different direction from the first direction X of the first gates 131. In addition, the third gates 135 and extend in vertical alignment with the quantum dots 1151.

FIG. 5 shows a first alternative embodiment of the second embodiment. According to this first alternative, the third gates 135 are oriented at 900 relative to the first gates 131. In addition, each third gate 135 is disposed between two adjacent second gates 132, in vertical alignment with the quantum dots 1151 disposed on a same column 115b of the array 115 of quantum dots.

The third gates 135 extend directly over the dielectric (in this case the dielectric layer 120) and intersect the first gates 131 (see FIG. 5) in a nested configuration similar to the nested configuration described previously (in connection with the second gates 132). The intersection zones between the first gates and the third gates are marked with the reference I_{G1,G3} in FIGS. 5 and 6.

Thus, each third gate 135 extends directly over the dielectric between two adjacent first gates 131 (or, in other words, into inter-first gate spaces), and passes over, or overlaps, the first gates 131 coated with the spacer layer 133 at the intersection zones I_{G1,G3}.

The height of the third gates 135 is greater than that of the second gates 132. Preferably, this height of the third gates is 20 nm to 50 nm greater than that of the second gates 132.

This nested configuration makes it possible to define a two-stage structure (a continuous conductive upper stage and a lower stage formed of a plurality of lower conductive regions) similar to the structure of the second gates 132 of the first embodiment.

This nested configuration thus makes it possible to form in each third gate 135, or in every second third gate 135, the inner structure previously described in connection with the first embodiment.

In the example shown in FIG. 5, each third gate 135 has the inner structure of the first type, illustrated in FIG. 2.

Thus, in these third gates 135, every second lower conductive region 1361 forms a conductive island 141. In addition, the upper conductive region 137 forms the common source of all the islands formed in the third gate, and conductive vias coated with the insulating layer form the drains 142.

This configuration enables the conductive islands to be positioned in vertical alignment with the quantum dots (unlike the first embodiment, where the 141 islands are in vertical alignment with the tunnel barriers).

As in the first embodiment, the islands 141 are disposed staggered relative to one another.

Of course, the third gates 135 may alternatively have the structure of the second type, illustrated in FIG. 4. In this case, in the third gates 135, each lower conductive region 1361 forms a conductive island 141. A charge detector 140 is then disposed in vertical alignment with each quantum dot 1151.

FIG. 6 shows a second alternative embodiment of the second embodiment. According to this second alternative, the third gates are oriented at 45° relative to the first and second gates 131, 132. Each third gate 135 extends in vertical alignment with the quantum dots disposed on a same diagonal 115c of the array 115 of quantum dots.

The third gates 135 extend directly over the dielectric (in this case the dielectric layer 120) and intersect the first and second gates 131, 132 in the same nested configuration as that described in connection with the alternative embodiment.

The intersection zones between the first and third gates I_{G1,G3} correspond to the intersection zones between the first and second gates I_{G1,G2}.

In the example shown in FIG. 6, each third gate 135 has the inner structure of the second type, illustrated in FIG. 4.

Thus, in these third gates 135, each lower conductive region 1361 forms a conductive island 141. In addition, the upper conductive region 137 forms the common source of all the islands formed in the third gate, and conductive vias coated in the insulating layer form the drains 142.

This configuration makes it possible to position a conductive island 141 in vertical alignment with each quantum dot 1151.

Of course, the third gates 135 may alternatively have the structure of the first type, illustrated in FIG. 5. In this case, in the third gates 135, every second lower conductive region 1361 forms a conductive island 141. A charge detector 140 is then shared between two quantum dots 1151.

From the above, the quantum device 100 comprises two sets of gates for controlling the quantum dots 1151: the first set includes the first gates 131; the second set includes gates that extend across the dielectric 120 and intersect the first gates 132. The second set includes, at least, the second gates 132.

In addition, the conductive island 141 of each charge detector 140 is formed by a region of one of the gates of the second set, said region being between two adjacent first gates 131 and disposed directly over the dielectric 120.

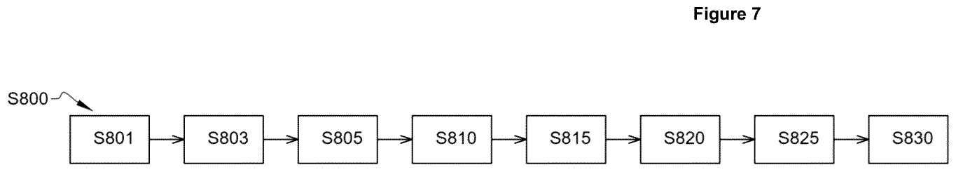

FIG. 7 shows a schematic representation of a block diagram of a method 800 for manufacturing the quantum device 100 illustrated in FIG. 2.

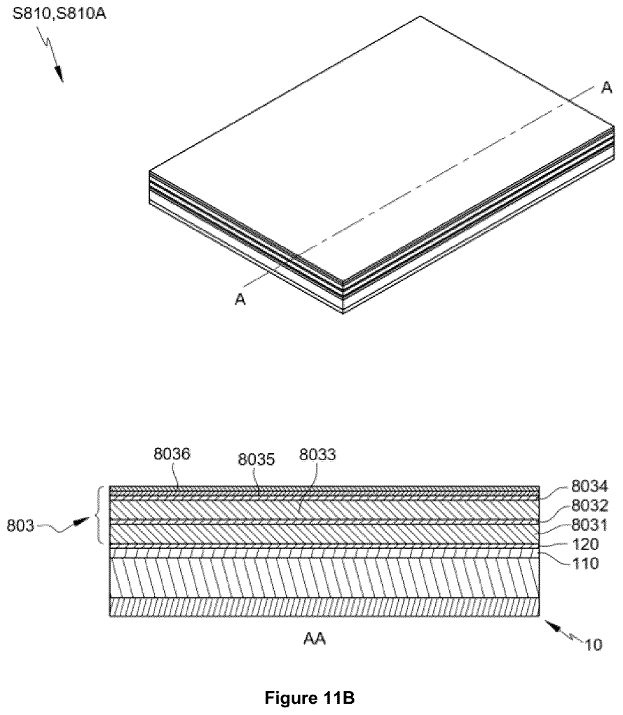

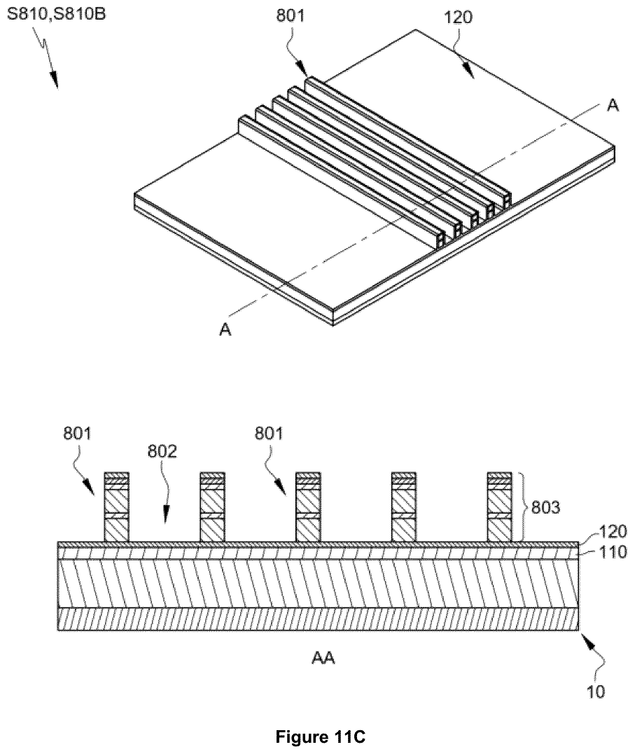

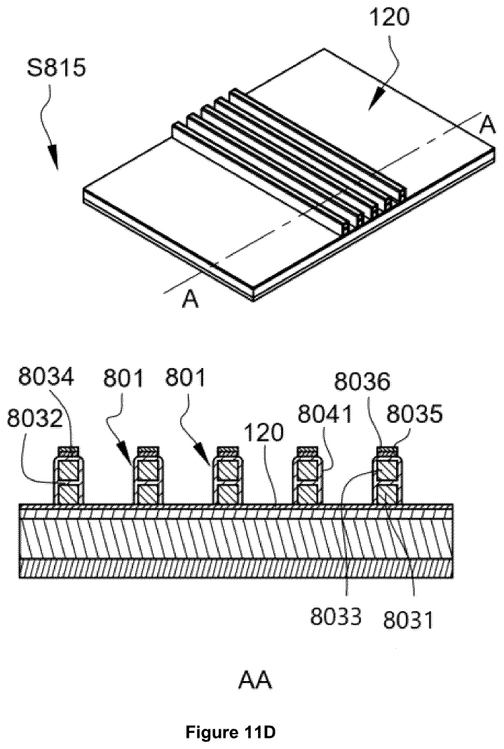

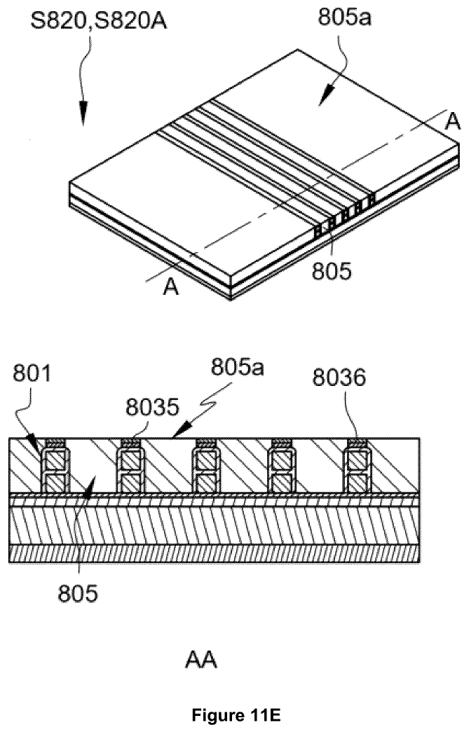

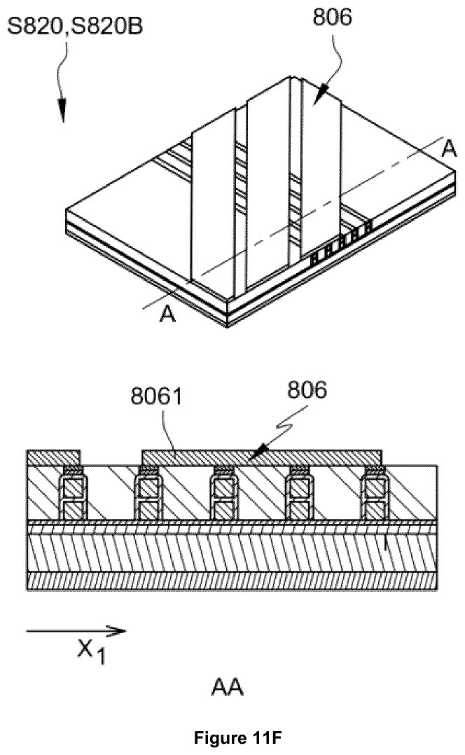

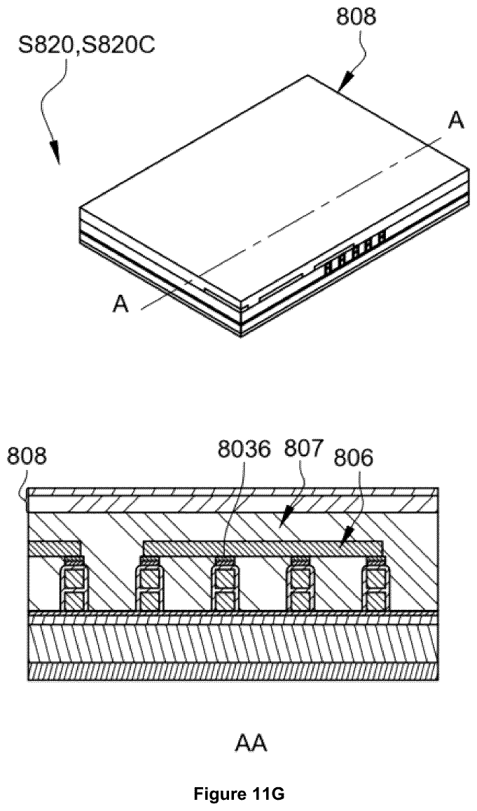

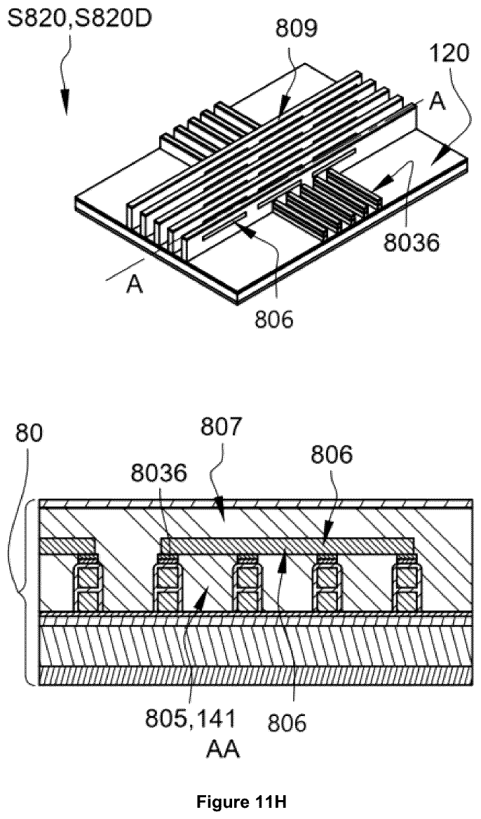

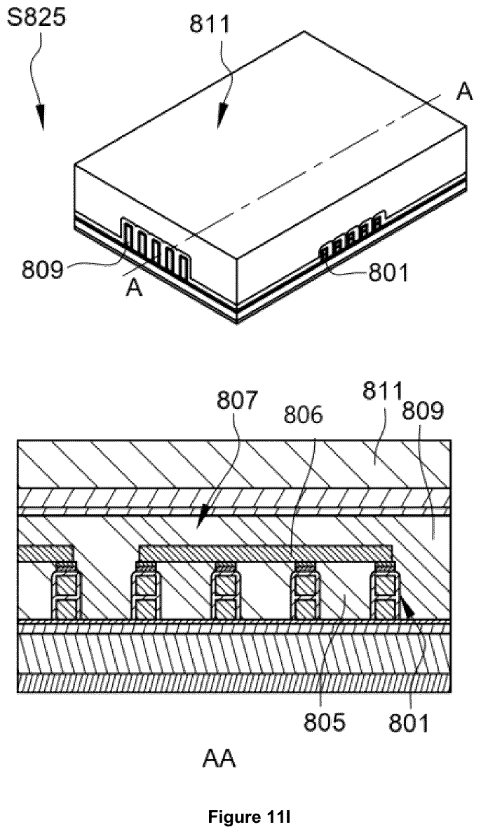

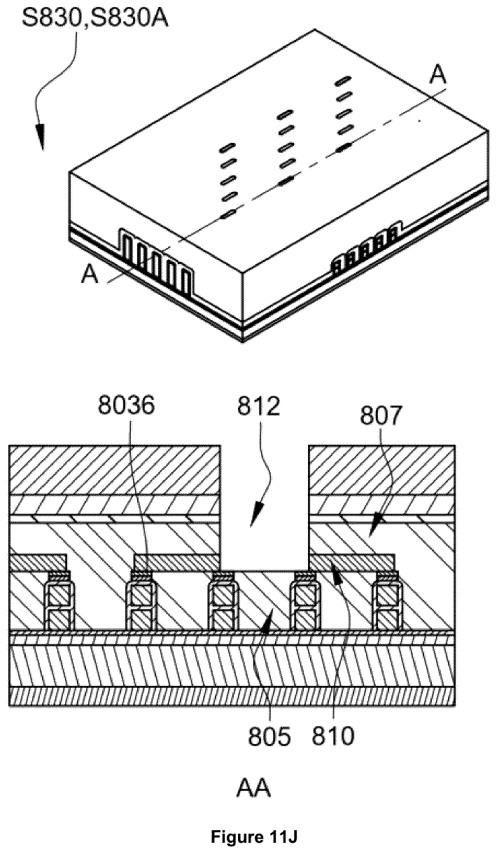

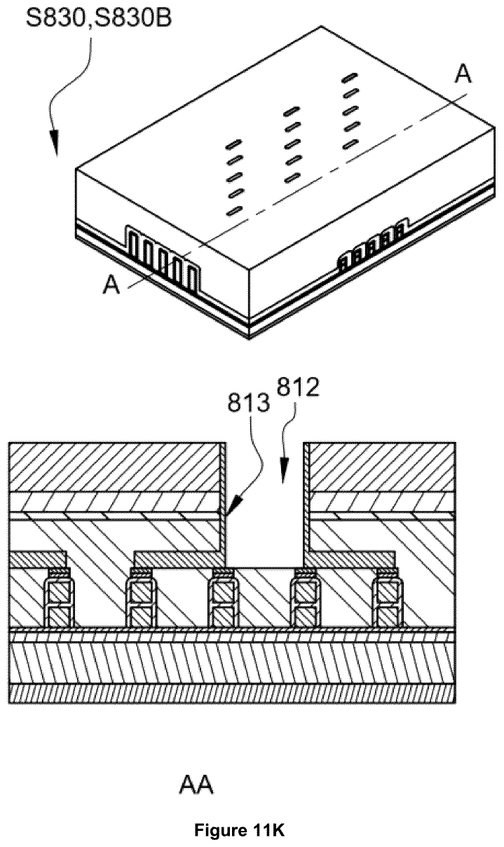

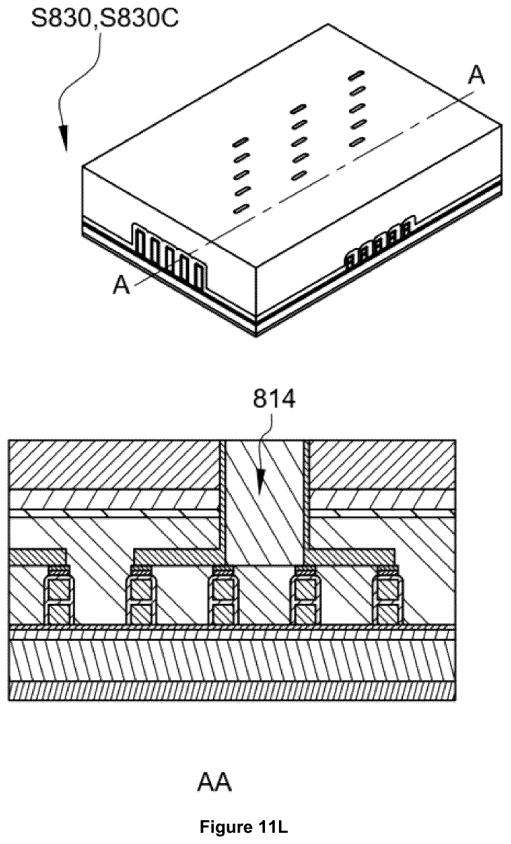

FIGS. 11A to 11L are schematic perspective cross-section views illustrating some steps or sub-steps of the manufacturing method 800.

The manufacturing method 800 begins with a first step S801 of providing the substrate, for example the SOI substrate 10. This substrate 10 comprises the semiconductor layer 110 on its front face 110a. This first step S801 is illustrated in FIG. 11A.

With reference to FIG. 7, this step S801 is followed by a step S803 (of defining the arrangement of the array 115 of quantum dots 1151 and the tunnel barriers 1152a, 1152b in the semiconductor layer 110). In other words, this step S803 consists in determining the regions of the semiconductor layer 110 in which the quantum dots 1151 will be formed, as well as the regions in which the tunnel barriers 1152a, 1152b will be formed.

With reference to FIG. 7, the method 800 continues with a step S805 of depositing a first dielectric layer 120 for forming the dielectric 120 of the device 100 (represented in FIG. 2) on the entire front face 110a of the semiconductor layer 110.

This third step, S805, is followed by a fourth step, S810, which is aimed at jointly creating the first gates 131, the gates 135 for controlling the charge detectors 140 and the tunnel layer 1441 (see FIG. 2).

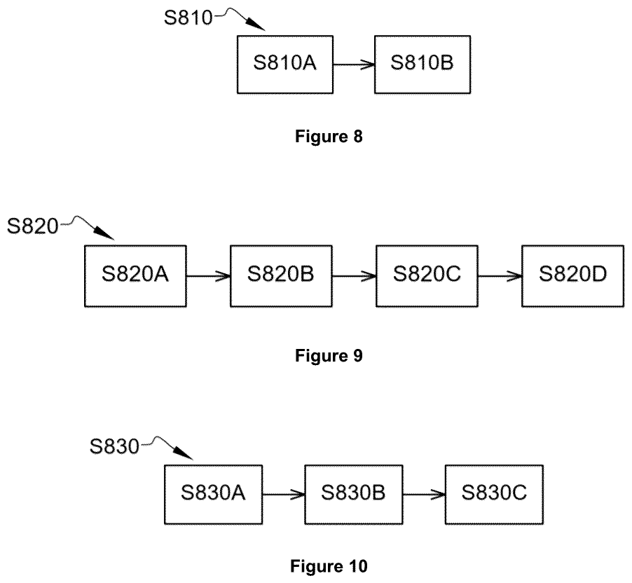

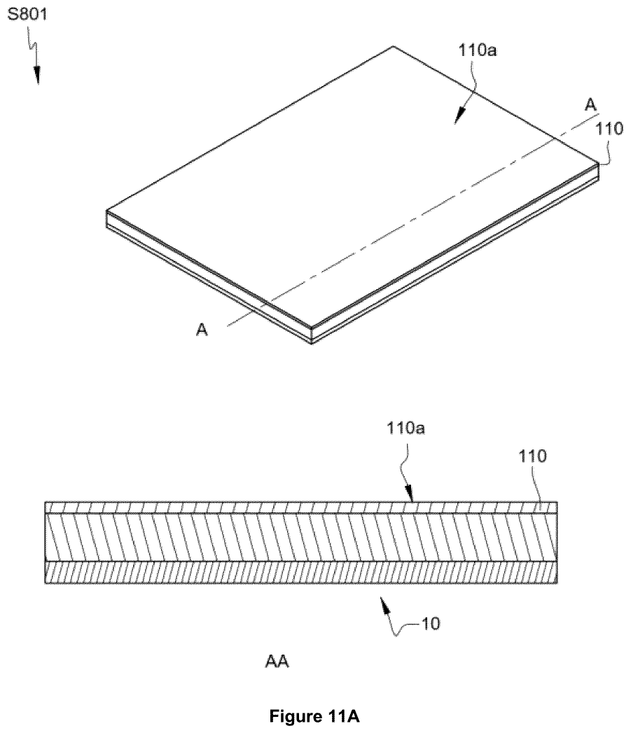

With reference to FIG. 8, this step S810 includes the successive sub-steps S810A and S810B. These sub-steps are also illustrated in FIGS. 11B and 11C.

With reference to FIG. 11B, sub-step S810A is a sub-step of forming a first stack 803 over the entire surface of dielectric 120, by:
Depositing, onto the dielectric layer 120, a first conductive layer 8031 made from the conductive material for forming the first gates 131,
Depositing, onto the first conductive layer 8031, a second dielectric layer 8032 made from the dielectric material forming the spacer 133. This second dielectric layer 8032 forms electrical insulation between the first conductive layer and the next conductive layer.
Depositing, onto the second dielectric layer 8032, a third conductive layer 8033 made from the conductive material for forming the control gates 135 of the charge detectors 140,
Depositing, onto the third conductive layer 8033, a fourth dielectric layer 8034. This fourth dielectric layer 8034 is formed with the material of the spacer 133. It is for forming the upper part of the insulating recesses 133_{R} (see FIG. 2),
Depositing, onto the fourth dielectric layer 8034, a fifth dielectric layer 8035 made from the dielectric material for forming the tunnel layer 1441 of the charge detectors 140,
Depositing, onto the fifth dielectric layer 8035, a layer 8036 of a hard mask material. This hard mask is, for example, formed from silicon nitride (SiN). This hard mask layer is hereinafter referred to as “first hard mask 8036”.

With reference to FIG. 11C, sub-step S810B is a sub-step of three dimensionally structuring the first stack 803 to form first strips 801 parallel to one another, disposed on the dielectric 120 on either side of the regions defined for the quantum dots 1151. Specifically, the first strips 801 are disposed facing the regions defined for the tunnel barriers 1152a connecting two adjacent quantum dots of a same row 115a of the array 115 of quantum dots.

The structuring sub-step S810B is carried out by successively etching the first hard mask 8036 and layers 8035, 8034, 8033 and 8032, and 8031 with stopping on dielectric 120.

In each first strip 801 thus formed, the first conductive layer 8031 forms one of the first gates 131 and the second conductive layer 8033 forms a gate 135 for controlling the charge detectors 140. The second conductive layer 8032 in turn provides insulation between these gates 131, 135.

Step S810 is followed by a fifth step S815, illustrated in FIG. 11D, consisting in carrying out conformal deposition of an encapsulation layer 8041 onto the flanks of the first strips 801. This encapsulation layer 8041 is made from the material forming the spacer 133.

Anisotropic etching is then implemented to remove the encapsulation layer 8041 deposited on at least one part of the flanks of the fifth dielectric layers 8035. Thus, at least one part of the flanks of the fifth layer 8035 is accessible, while the other layers 8034, 8033, 8032 and 8031 are covered, on their flanks, with the encapsulation layer 8041. Anisotropic etching is further configured to remove the encapsulation layer 8041 deposited onto the dielectric layer 120 between the first strips 801.

At the end of this step S815, the insulating recesses 133_{R} of the second gates 132 are prepared.

The method 800 continues with a sixth step S820, the purpose of which is to jointly form the first gates 131 and the islands 141 of the charge detectors 140.

With reference to FIG. 9, step S820 preferably includes the sub-steps S820A, S820B, S820C and S820D illustrated in FIGS. 11E, 11F, 11G and 11H respectively.

With reference to FIG. 11E, sub-step S820A consists in forming lower conductive strips 805 by filling the zones 802 (see FIG. 11C) of the dielectric 120 located between the first strips 801 with the conductive material for forming the second gates 132. Filling is carried out up to the height of the hard mask layer 8036. The fifth dielectric layers 8035 are thus embedded, and thus integrated, into these lower conductive strips 805.

Thus, at the end of this first sub-step S820A, the lower conductive regions 1361 of the second gates 131 are made. In addition, the tunnel layer 1441 of each charge detector 140 has been formed (by the fifth layer 8035). Each lower conductive region 1361 made is thus prepared to form an island 141 of a charge detector 140.

It is noted that the first strips 801 advantageously provide an alignment reference for forming the islands 141. In other words, the islands 141 are defined in a self-aligned manner in the inter-first gate spaces, by virtue of the first strips 801 and this step S820. This self-alignment avoids the need for lithography steps.

The second sub-step S820B, illustrated in FIG. 11F, consists in depositing a layer 8061 of the material for forming the upper barrier layer 1442 onto the surface 805a (see FIG. 11E) formed by all the lower conductive strips 805 and the hard mask layers 8036. This deposition is followed by an operation of three-dimensionally structuring this layer 8061 to form strips 806. With reference to FIG. 11F, these upper barrier layer strips 806 are preferentially parallel to each other and oriented at 45° relative to the first strips 801. Furthermore, in a direction X1 perpendicular to the first strips 801, each upper barrier layer strip 806 overlaps three lower conductive strips 805 as well as the four complementary first strips 801. Each upper barrier layer strip 806 is further separated from adjacent upper barrier layer strips 806 by a space corresponding to a lower conductive strip 805.

The orientation of the upper barrier layer strips 806 enables the desired periodicity of the charge detectors 140 in the quantum device 100 to be achieved. Here, the 45° orientation enables periodicity of every other island 141 formed in a bottom conductive region 1361 (i.e. one charge detector 140 for two quantum dots 1151) to be achieved.

The third sub-step S820C, illustrated in FIG. 11G, firstly consists in depositing the conductive material for forming the second gates 132 over the whole of the dielectric strips 806 and the lower conductive strips 805. This material is identical to the material of the lower strips 805. At the end of this step S820C, the device is thus covered with a conductive layer 807 which will be used to form the upper conductive layer 137 of the second gates 132.

This deposition operation is followed by an operation of planarising the upper conductive layer 807.

The planarisation operation then continues with an operation of depositing a hard mask layer 808 onto the upper conductive layer 807 planarised.

The fourth sub-step S820D, illustrated in FIG. 11H, consists in structuring the stack 80 formed by the lower conductive strips 805 and the upper conductive layer 807 to form the first and second gates 131, 132.

This structuring comprises defining an etching mask in the second hard mask layer 808 (see FIG. 11G).

The etching mask defines strips corresponding to the first strips 801 and second strips 809 parallel to each other and oriented perpendicularly to the first strips 801.

Etching the stack 80 through the etching mask is then implemented. Etching stops on the dielectric layer 120 (between the first strips 801) and on the hard mask layer 8036 on the first strips 801.

At the end of this step S820, the first and second gates 131, 132 are formed in the nested configuration described in connection with the first embodiment, and each second gate 132 forms a plurality of islands 141 of charge detectors 140 (in the regions corresponding to the lower conductive strips 805) and a common source 143 (in the region corresponding to the upper conductive layer 807).

Step S820 preferably continues with a step S825, illustrated in FIG. 11I, of forming an encapsulation layer 811, for example by depositing a dielectric PMD (acronym for “Pre-metal Deposition”) layer on the dielectric 120 so as to embed the first strips 801 and the second strips 809.

Step S825 continues with step S830 of forming the drains 142 (or sources 143) of the charge detectors 140. This step S830 comprises the sub-steps S830A, S8030B and S830C illustrated in FIGS. 11J to 11L.

Sub-step S830A, illustrated in FIG. 11J, consists in making openings 812 through the encapsulation layer 811 (if the encapsulation step S825 is performed) and through the second strips 809 so that each opening 812 opens into the lower conductive strip 805 disposed in the centre of the three lower conductive strips covered with the upper barrier layer 806.

Sub-step S830B, illustrated in FIG. 11K, consists in conformally depositing onto the side walls of the openings 812, a layer 813 of the material forming the insulating layer 1422 coating the conductive vias 1421 (forming the drains 142). This insulating layer 813 forms insulation between the upper conductive strip 807 and the internal volume of the opening 812.

Sub-step S830C, illustrated in FIG. 11L, consists in filling the openings 812 with the conductive material for forming the drains or sources 142, 143 of the charge detectors 140.

The openings 812 thus insulated and filled form the through conductive vias 814, coated with insulator which define the drains 142 (or sources 143) of the charge detectors 140.

1. A quantum device comprising:
a semiconductor layer adapted to form a two-dimensional array of quantum dots, the semiconductor layer having a front face
a dielectric, disposed on the front face of the semiconductor layer,
first lines of gates and second lines of gates to control the quantum dots, the first lines of gates and the second lines of gates extending directly over the dielectric, each second line of gates intersecting the first lines of gates, the first and second lines of gates defining a network of two-dimensional meshes, each two-dimensional mesh facing a quantum dot, the first lines of gates and the second lines of gates being lines of coupling gates,
charge detectors, each charge detector comprising a conductive island, a source and a drain,
the conductive island of each charge detector being formed at the level of a two-dimensional mesh, between two adjacent first lines of gates and directly over the dielectric, the charge detectors forming lines of charge detectors such that one among the source and the drain of each charge detector of a same line of charge detectors is in electrical contact with a same metallisation row, and such that the other among the drain and the source of each charge detector is common for each charge detector of a same line of charge detectors.

2. The quantum device according to claim 1, wherein the conductive island of each charge detector is integrated into one of the second lines of gates.

3. The quantum device according to claim 1, wherein the drain of each charge detector comprises a conductive via coated with an electrically insulating material, the coated conductive via having an end disposed in contact with a barrier layer disposed in vertical alignment with the conductive island of said charge detector.

4. The quantum device according to claim 1, wherein the conductive island of each charge detector is formed in a line of gates for controlling quantum dots distinct from the first lines of gates, said line of gates intersecting the first lines of gates and extending directly over the dielectric, said line of gates having recesses covered with an electrically insulating layer, the insulating recesses being disposed at the intersections of said line of gates with the first lines of gates, each insulating recess accommodating a first line of gates, the insulating recesses defining, in said line of gates, a plurality of lower conductive regions extending directly over the dielectric, and a continuous upper conductive region.

5. The quantum device according to claim 4, wherein said line of gates is one of the second lines of gates.

6. The quantum device according to claim 3, wherein said line of gates is a third line of gates of a set of third lines of gates for controlling chemical potential of the quantum dots, each third line of gates being disposed in vertical alignment with the quantum dots formed along a column or diagonal of the array of quantum dots, the third lines of gates controlling the potential of the charge detectors.

7. The quantum device according to claim 3, wherein said line of gates has an inner structure of a first type comprising:
a tunnel layer covering each insulating recess of said line of gates,
every fourth lower conductive region extending from the upper conductive region towards the dielectric, said every fourth lower conductive region defining three complementary lower regions,
the two lower conductive regions located at the ends of the three complementary lower regions being covered with an upper barrier layer, the upper barrier layer being partly disposed on the tunnel layers,
the lower conductive region located in the centre of the three complementary lower regions extending to a conductive via coated with an electrically insulating material, said coated conductive via passing through the upper conductive region to the upper barrier layer.

8. The quantum device according to claim 4, wherein the inner structure of said second line of gates is of a second type comprising:
a barrier layer covering all the lower conductive regions of said line of gates, the barrier layer being continuous and disposed on the insulating recesses of said line of gates,
conductive vias coated with an electrically insulating material passing through the upper conductive region to the barrier layer, each conductive via having an end disposed for one part in vertical alignment with a lower conductive region and for the other part in vertical alignment with one of the insulating recesses adjacent to said lower conductive region.

9. The quantum device according to claim 5, wherein the quantum device comprises lines of gates for controlling chemical potentials of the conductive islands, each line of gates for controlling chemical potentials extending over one of the first lines of gates and being housed under the insulating recesses of the second lines of gates at the intersections of the first and second lines of gates.

10. The quantum device according to claim 1, wherein the semiconductor layer comprises holes to form the quantum dots.

11. A method for manufacturing a quantum device comprising charge detectors, each charge detector comprising a conductive island, a drain and a source, the method comprising:
providing a semiconductor layer adapted to form a two-dimensional array of quantum dots, said semiconductor layer having a front face, said semiconductor layer comprising a dielectric disposed on the front face and first lines of gates to control the quantum dots, the first lines of gates extending directly over the dielectric, the first lines of gates being lines of coupling gates,
coating the flanks and upper face of each first line of gates to house each first line of gates under an insulating recess,
defining, the conductive islands from the first coated lines of gates, each conductive island extending between two adjacent first lines of gates and directly over the dielectric,
forming, from the conductive islands defined, second lines of gates to control, with the first lines of gates, the quantum dots, each second line of gates extending directly over the dielectric and intersecting the first lines of gates, the first and second lines of gates forming a network of two-dimensional meshes on the dielectric, the second lines of gates being lines of coupling gates, the charge detectors forming lines of charge detectors such that one among the source and the drain of each charge detector of a same line of charge detectors is in electrical contact with a same metallisation row, and such that the other among the drain and the source of each charge detector is common for each charge detector of a same line of charge detectors.

12. The manufacturing method according to claim 11, wherein the step of defining the conductive islands comprises the following sub-steps of:
filling, with a conductive material, the spaces of the dielectric which are delimited by two adjacent first lines of gates coated, filling stopping at the height of insulating recesses,
forming a barrier layer over the entire surface obtained after filling,
structuring the barrier layer to form barrier strips oriented at a predetermined angle relative to the first lines of gates.

13. The manufacturing method according to claim 12, wherein the predetermined angle is such that the barrier strips are oriented at 45° relative to the direction of the first lines of gates, the barrier strips extending, in the direction perpendicular to the first lines of gates, over four adjacent conductive strips.

14. The manufacturing method according to claim 11, comprising, after the step of forming the second lines of gates, a step of making conductive vias coated with an electrically insulating material, each conductive via passing through an upper region of one of the second lines of gates with stopping on a region of a dielectric barrier strip, the conductive via forming the drain of the conductive island defined in vertical alignment with the region of the barrier strip.
